(19) United States
(12) Patent Application Publication
(10) Pub. No.: US 2004/0191995 A1
(43) Pub. Date: Sep. 30, 2004

(54) Method of manufacturing a semiconductor device

(76) Inventor: Sumio Koiwa, Chiba-shi (JP)

Correspondence Address: ADAMS & WILKS, 31st FLOOOR, 50 BROADWAY, NEW YORK, NY, 10004, US

(21) Appl. No.: 10/803,778

(22) Filed: Mar. 18, 2004

(30) Foreign Application Priority Data
Mar. 19, 2003 (JP) 2003-075343
Nov. 18, 2003 (JP) 2003-387730

(51) Int. Cl. H01L 29/74

(52) U.S. Cl. 438/270

(57) ABSTRACT

Provided is a manufacturing method for realizing a low cost and high performance vertical MOSFET. The vertical MOSFET manufacturing method of the present invention gives the portion formed between the trench and the semiconductor substrate flat portion a smooth shape by doping the semiconductor substrate with an impurity through ion implantation and then thermally oxidizing the substrate. The withstand voltage of the gate insulating film is thus improved. Furthermore, the semiconductor device manufacturing method of the present invention puts the formation of the N+ diffusion layer serving as a source after the formation of the trench and the subsequent formation of the gate electrode in the trench, and therefore can avoid re-diffusion of the N+ diffusion layer, which otherwise causes an increase in leak current.

### BACKGROUND OF THE INVENTION

1. Field of the Invention

The present invention relates to a method of manufacturing a semiconductor device and, more particularly, to a method of manufacturing a vertical MOSFET that has a trench structure.

2. Description of the Related Art

Prior art of the field is described with reference to FIG. 5, which shows a vertical MOSFET. An N− type semiconductor substrate 2 is placed under a P− type diffusion layer 3, and an N+ type semiconductor substrate 1 is placed under the N− semiconductor substrate 2. A trench 6 is formed deep enough to reach the N− semiconductor substrate 2 through the P− type diffusion layer 3. A gate insulating film 7 is formed on a surface of the trench 6. A gate electrode 8 formed of polycrystalline silicon or the like is buried in the trench 6. An N+ type diffusion layer 5 is formed in the P− type diffusion layer 3 (see JP 03-238870 A, for example).

In the vertical MOSFET of FIG. 5, a given threshold voltage or higher voltage is applied to the gate electrode 8 to form an N type inversion layer along the trench in the P− type diffusion layer 3 between the N+ type semiconductor substrate 1 (heavily doped drain) and the N− semiconductor substrate 2 (lightly doped drain) which serve as drains and the N+ type diffusion layer 5 which serves as a source. This opens an electric current path. The source-drain of the vertical MOSFET is thus turned on and is turned off when the N type inversion layer in the P− type diffusion layer 3 is removed by setting the voltage of the gate electrode 8 lower than the threshold voltage. The thus structured vertical MOSFET is far larger in current path area than planar MOSFETs and therefore has an advantage of being low in ON resistance.

Now, a method of manufacturing the vertical MOSFET of FIG. 5 is outlined. First, the N+type semiconductor substrate 1 having on its surface the N− semiconductor substrate 2 is prepared to form the P− type diffusion layer 3 on the substrate 2 by, for example, ion implantation. Then ion implantation or other method is used to form the N+ type diffusion layer 5. The trench 6 is formed to reach the levels of the P− type diffusion layer 3 and the N-type semiconductor substrate 2 piercing through the center of the N+ type diffusion layer 5. The gate oxide film 7 is formed in the trench 6, which is then filled with polycrystalline silicon to form the buried gate electrode 8.

The semiconductor device obtained by the above-described manufacturing method of prior art has the following problem:

The manufacturing method requires various kinds of heat treatment including one for repairing crystal defects after the N+ type diffusion layer 5 and then the trench 6 are formed, one for forming the gate insulating film 7, and CVD heat treatment for forming the gate electrode 8. These heat treatment steps cause re-diffusion of the N+ type diffusion layer 5, which leads to an increase in leak current between the source and the drain.

A solution to this problem is to form the N+ type diffusion layer 5 by, for example, ion implantation, after the trench 6, the gate insulating film 7, and the gate electrode 8 are formed. However, the solution raises another problem of lowered withstand voltage of the gate insulating film since the method places the trench 6 approximately at right angles with the flat portion of the N+ type diffusion layer 5 and accordingly brings stress concentration and gate electric field concentration to this portion.

The gate insulating film could be prevented from having low withstand voltage by taper etching of the trench 6, but this increases the area of the vertical MOSFET.

### SUMMARY OF THE INVENTION

The present invention has been made in view of the above, and an object of the present invention is to provide a method of manufacturing a high performance semiconductor device.

In order to attain the above-mentioned object, the present invention provides the following methods.

(1) A method of manufacturing a semiconductor device, including:

a step of forming a semiconductor layer of a second conductivity type on a semiconductor substrate of a first conductivity type;

a step of introducing an impurity in the semiconductor layer of the second conductivity type;

a step of forming a trench that pierces semiconductor layer of the second conductivity type to reach the semiconductor substrate of the first conductivity type;

a step of forming an insulating film on a surface of the semiconductor substrate of the first conductivity type, on a surface of the semiconductor layer of the second conductivity type, and on side walls and bottom of the trench;

a step of forming a gate electrode in the trench; and

a step of forming a heavily doped layer of the first conductivity type in the semiconductor layer of the second conductivity type.

(2) A method of manufacturing a semiconductor device in which the impurity introduced in the semiconductor layer of the second conductivity type which is formed on the semiconductor substrate of the first conductivity type is an impurity of a first conductivity type.

(3) A method of manufacturing a semiconductor device in which the impurity of the first conductivity type introduced in the semiconductor layer of the second conductivity type which is formed on the semiconductor substrate of the first conductivity type is arsenic or phosphorus.

(4) A method of manufacturing a semiconductor device in which the impurity introduced in the semiconductor layer of the second conductivity type which is formed on the semiconductor substrate of the first conductivity type is an inert element.

(5) A method of manufacturing a semiconductor device in which the impurity of the first conductivity type introduced in the semiconductor layer of the second conductivity type which is formed on the semiconductor substrate of the first conductivity type is argon.

(6) A method of manufacturing a semiconductor device in which ion implantation is employed in the step of introducing an impurity in the semiconductor layer of the second conductivity type which is formed on the semiconductor substrate of the first conductivity type.

(7) A method of manufacturing a semiconductor device in which the impurity is introduced in the semiconductor layer of the second conductivity type which is formed on the semiconductor substrate of the first conductivity type in a concentration of 1×10¹⁷ atoms/cm³ to 1×10¹⁸ atoms/cm³.

(8) A method of manufacturing a semiconductor device in which the inert element is introduced in the semiconductor layer of the second conductivity type which is formed on the semiconductor substrate of the first conductivity type in a concentration of 5 ×10¹⁷ atoms/cm³ to 1×10¹⁸ atoms/cm³.

(9) A method of manufacturing a semiconductor device in which thermal oxidation is employed in the step of forming an insulating film on a surface of the semiconductor substrate of the first conductivity type, on a surface of the semiconductor layer of the second conductivity type, and on side walls and bottom of the trench.

As has been described, the vertical MOSFET manufacturing method of the present invention gives the portion formed between the trench and the semiconductor substrate flat portion a smooth shape by doping the semiconductor substrate with an impurity through ion implantation and then thermally oxidizing the substrate. The withstand voltage of the gate insulating film is thus improved. Furthermore, the semiconductor device manufacturing method of the present invention puts the formation of the N+ diffusion layer serving as a source after the formation of the trench and the subsequent formation of the gate electrode in the trench, and therefore can avoid re-diffusion of the N+ diffusion layer, which otherwise causes an increase in leak current.

A low-cost, high-performance semiconductor device can be obtained by the semiconductor device manufacturing method of the present invention.

### BRIEF DESCRIPTION OF THE DRAWINGS

In the accompanying drawings:

FIGS. 1A to 1C are schematic sectional diagrams showing the flow of a semiconductor device manufacturing method according to Embodiment 1 of the present invention;

FIG. 2 is a graph showing the relation between the N− diffusion layer concentration and the vertical MOSFET withstand voltage;

FIGS. 3A to 3C are schematic sectional diagrams showing the flow of a semiconductor device manufacturing method according to Embodiment 2 of the present invention;

FIG. 4 is a graph showing the relation between the argon concentration and the vertical MOSFET withstand voltage; and

FIG. 5 is a sectional view showing a conventional method of manufacturing a semiconductor device.

### DETAILED DESCRIPTION OF THE PREFERRED EMBODIMENTS

Preferred embodiments of the present invention will be described below with reference to the accompanying drawings.

### Embodiment 1

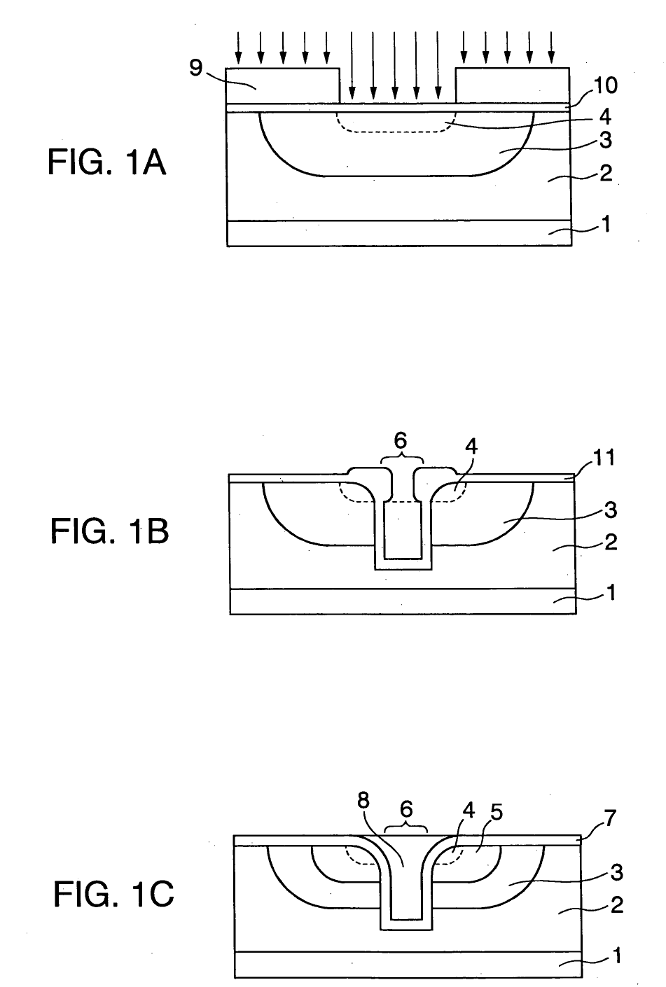

FIGS. 1A to 1C are schematic sectional diagrams showing the flow of a semiconductor device manufacturing method according to Embodiment 1 of the present invention. In FIG. 1A, an N+ type semiconductor substrate 1 is, for example, a semiconductor substrate which is doped with arsenic in a concentration that gives the substrate a resistivity of 1 mΩcm to 10 mΩcm. An N− type semiconductor substrate 2 is, for example, a semiconductor substrate which is doped with phosphorus in a concentration that gives the substrate a resistivity of 0.1 Ωcm to 1 Ωcm. The N− type semiconductor substrate 2 is placed on the N+ type semiconductor substrate 1, and is doped with an impurity through ion implantation to form a P− type diffusion layer 3. The impurity used is, for example, boron and the impurity concentration is set to 1×10¹⁶ atoms/cm³ to 1×10¹⁸ atoms/cm³. The ion implantation is followed by heat treatment for diffusing the P− type diffusion layer 3 to a desired depth. After the heat treatment, a photoresist mask 9 is formed to form an N− diffusion layer 4 through ion implantation of a first conductivity type impurity, for example, arsenic, in a concentration of 1×10¹⁷ atoms/cm³ to 1×10¹⁸ atoms/cm³.

In FIG. 1B, the photoresist mask 9 is peeled off and a trench 6 is formed. The formation of the trench 6 produces a defective layer, which is removed by thermal oxidation. The N− diffusion layer 4 is oxidized at an increased speed because of defects brought by the ion implantation for forming the N− diffusion layer.

In FIG. 1C, an oxide film formed by the thermal oxidation is removed to remove the defects brought by the formation of the trench and to give a flat portion of the P− type diffusion layer 3 including the trench 6 and the N− diffusion layer 4 a smooth shape. Thereafter, a gate insulating film 7 is formed to a thickness of 100 to 1000 angstrom in a dry oxidation atmosphere, for example. Next, polycrystalline silicon or the like is buried in the trench 6 by CVD and doped with phosphorus or boron to have an electric conductivity. The polycrystalline silicon then receives etch-back to form a gate electrode 8. After that, a photoresist mask is formed to form an N+ type diffusion layer 5 through ion implantation of an impurity, for example, arsenic, in a concentration of 5×10¹⁹ atoms/cm³.

The source-drain leak current is prevented through the above steps and thus a vertical MOSFET that is improved in gate insulating film withstand voltage can be manufactured without increasing the MOSFET area. Re-diffusion of the N+ type diffusion layer that serves as a source and an accompanying increase in leak current between the source and the drain are avoided in the semiconductor device manufacturing method of the present invention by forming the N+ type diffusion layer after the formation of the trench and the formation of the gate electrode in the trench.

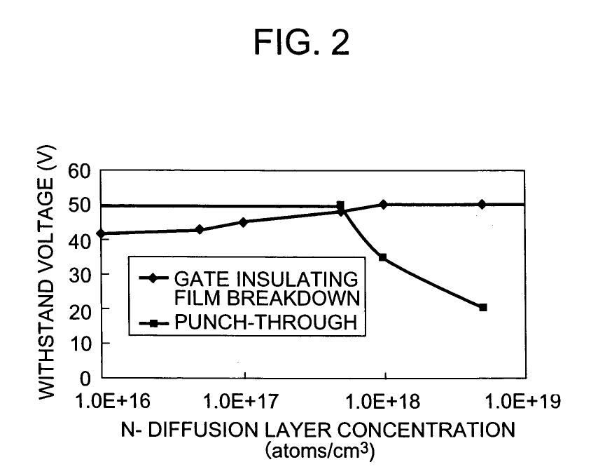

FIG. 2 shows the relation between the concentration of the impurity for forming the N− diffusion layer 4 and the withstand voltage of the vertical MOSFET. As shown in FIG. 2, there is an optimum value in the relation between the concentration of the N− type diffusion layer 4 and the withstand voltage of the vertical MOSFET, and the N− diffusion layer 4 preferably has an impurity concentration of 1×10¹⁷ atoms/cm³ to 1×10¹⁸ atoms/cm³. Since the N− diffusion layer 4 is ultimately placed in the N+ type diffusion layer 5, the formation of the N− diffusion layer 4 does not have an electric influence over the vertical MOSFET.

### Embodiment 2

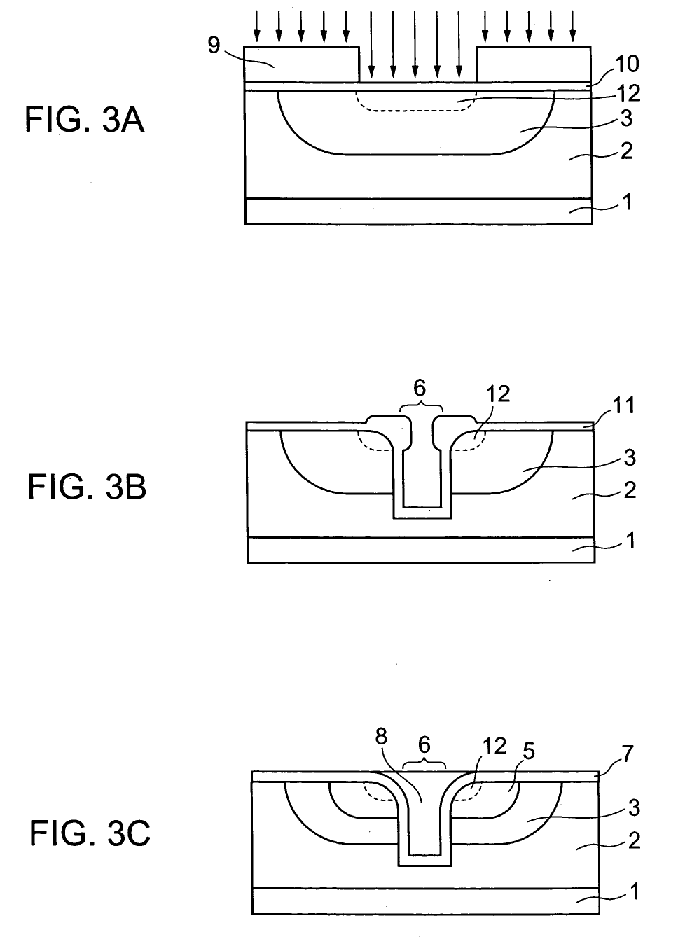

FIGS. 3A to 3C are schematic sectional diagrams showing the flow of a semiconductor device manufacturing method according to Embodiment 2 of the present invention. In FIG. 3A, an N+ type semiconductor substrate 1 is, for example, a semiconductor substrate which is doped with arsenic in a concentration that gives the substrate a resistivity of 1 mΩcm to 10 mΩcm. An N− semiconductor substrate 2 is, for example, a semiconductor substrate which is doped with phosphorus in a concentration that gives the substrate a resistivity of 0.1 Ωcm to 1 Ωcm. The N− semiconductor substrate 2 is placed on the N+ type semiconductor substrate 1, and is doped with an impurity through ion implantation to form a P− type diffusion layer 3. The impurity used is, for example, boron and the impurity concentration is set to 1×10¹⁶ atoms/cm³ to 1×10¹⁸ atoms/cm³. The ion implantation is followed by heat treatment for diffusing the P− type diffusion layer 3 to a desired depth. After the heat treatment, a photoresist mask 9 is formed to form a diffusion layer 12 through ion implantation of an inert element, for example, argon, in a concentration of 5 ×10¹⁷ atoms/cm³ to 1×10¹⁸ atoms/cm³.

In FIG. 3B, the photoresist mask 9 is peeled off and a trench 6 is formed. The formation of the trench 6 produces a defective layer, which is removed by thermal oxidation. The diffusion layer 12 is oxidized at an increased speed because of defects brought by the ion implantation for forming the diffusion layer.

In FIG. 3C, an oxide film formed by the thermal oxidation is removed to remove the defects brought by the formation of the trench and to give a flat portion of the P− type diffusion layer 3 including the trench 6 and the diffusion layer 12 a smooth shape. Thereafter, a gate insulating film 7 is formed to a thickness of 100 to 1000 angstrom in a dry oxidation atmosphere, for example. Next, polycrystalline silicon or the like is buried in the trench 6 by CVD and doped with phosphorus or boron to have an electric conductivity. The polycrystalline silicon then receives etch-back to form a gate electrode 8. After that, a photoresist mask is formed to form an N+ type diffusion layer 5 through ion implantation of an impurity, for example, arsenic, in a concentration of 5×10¹⁹ atoms/cm³.

The source-drain leak current is prevented through the above steps and thus a vertical MOSFET that is improved in gate insulating film withstand voltage can be manufactured without increasing the MOSFET area. Re-diffusion of the N+ type diffusion layer that serves as a source and an accompanying increase in leak current between the source and the drain are avoided in the semiconductor device manufacturing method of the present invention by forming the N+ type diffusion layer after the formation of the trench and the formation of the gate electrode in the trench.

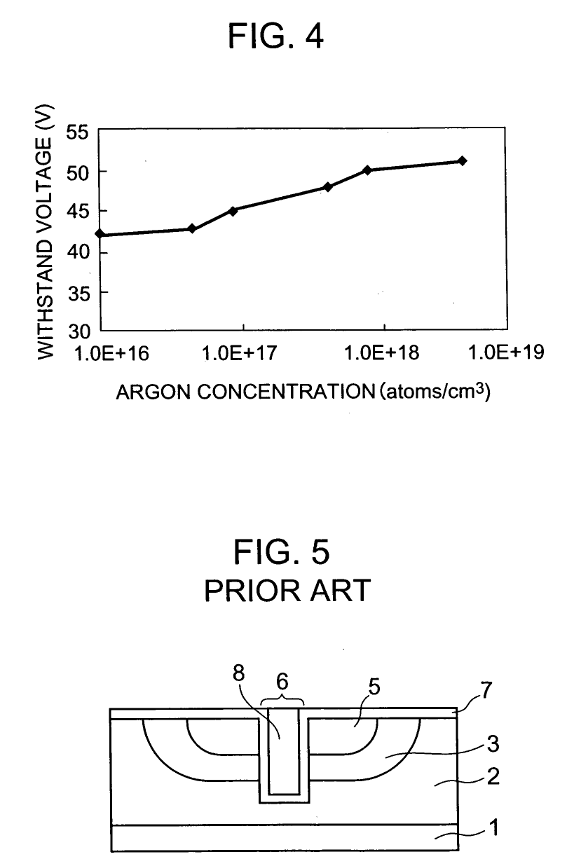

FIG. 4 shows the relation between the concentration of argon for forming the diffusion layer 12 and the withstand voltage of the vertical MOSFET. As shown in FIG. 4, the relation between the concentration of the diffusion layer 12 and the withstand voltage of the vertical MOSFET exhibits saturation characteristics. It is therefore preferable for the diffusion layer 12 to have a concentration of 5×10¹⁷ atoms/cm³ or more. Since the diffusion layer 12 is ultimately placed in the N+ type diffusion layer 5, the formation of the diffusion layer 12 does not have an electric influence over the vertical MOSFET.

The descriptions given above are merely examples of how the present invention is carried out and it goes without saying that various modifications can be thought of without departing from the spirit of the present invention. For instance, Embodiments 1 and 2 of the present invention which deal with N-channel MOSFETs are also applicable to P-channel MOSFETs by changing the polarities of the semiconductor layers and diffusion layers.

What is claimed is:

1. A method of manufacturing a semiconductor device, comprising:
a step of forming a semiconductor layer of a second conductivity type on a semiconductor substrate of a first conductivity type;
a step of introducing an impurity in the semiconductor layer of the second conductivity type;
a step of forming a trench that pierces the semiconductor layer of the second conductivity type to reach the semiconductor substrate of the first conductivity type;
a step of forming an insulating film on a surface of the semiconductor substrate of the first conductivity type, on a surface of the semiconductor layer of the second conductivity type, and on side walls and bottom of the trench;
a step of forming a gate electrode in the trench; and
a step of forming a heavily doped layer of the first conductivity type in the semiconductor layer of the second conductivity type.

2. A method of manufacturing a semiconductor device according to claim 1, wherein the impurity introduced in the semiconductor layer of the second conductivity type which is formed on the semiconductor substrate of the first conductivity type is an impurity of a first conductivity type.

3. A method of manufacturing a semiconductor device according to claim 2, wherein the impurity of the first conductivity type introduced in the semiconductor layer of the second conductivity type which is formed on the semiconductor substrate of the first conductivity type is arsenic or phosphorus.

4. A method of manufacturing a semiconductor device according to claim 1, wherein the impurity introduced in the semiconductor layer of the second conductivity type which is formed on the semiconductor substrate of the first conductivity type is an inert element.

5. A method of manufacturing a semiconductor device according to claim 2, wherein the impurity of the first conductivity type introduced in the semiconductor layer of the second conductivity type which is formed on, the semiconductor substrate of the first conductivity type is argon.

6. A method of manufacturing a semiconductor device according to claim 1, wherein ion implantation is employed in the step of introducing an impurity in the semiconductor layer of the second conductivity type which is formed on the semiconductor substrate of the first conductivity type.

7. A method of manufacturing a semiconductor device according to claim 3, wherein the impurity is introduced in the semiconductor layer of the second conductivity type which is formed on the semiconductor substrate of the first conductivity type in a concentration of 1×10¹⁷ atoms/cm³ to 1×10¹⁸ atoms/cm³.

8. A method of manufacturing a semiconductor device according to claim 5, wherein the inert element is introduced in the semiconductor layer of the second conductivity type which is formed on the semiconductor substrate of the first conductivity type in a concentration of 5×10¹⁷ atoms/cm³ to 1×10¹⁸ atoms/cm³.

9. A method of manufacturing a semiconductor device according to claim 1, wherein thermal oxidation is employed in the step of forming an insulating film on a surface of the semiconductor substrate of the first conductivity type, on a surface of the semiconductor layer of the second conductivity type, and on side walls and bottom of the trench.

10. A method of manufacturing a semiconductor device according to claim 2, wherein the impurity is introduced in the semiconductor layer of the second conductivity type which is formed on the semiconductor substrate of the first conductivity type in a concentration of 1×10¹⁷ atoms/cm³ to 1×10¹⁸ atoms/cm³.

11. A method of manufacturing a semiconductor device according to claim 1, wherein the impurity is introduced in the semiconductor layer of the second conductivity type which is formed on the semiconductor substrate of the first conductivity type in a concentration of 1×10¹⁷ atoms/cm³ to 1×10¹⁸ atoms/cm³.

12. A method of manufacturing a semiconductor device according to claim 4, wherein the inert element is introduced in the semiconductor layer of the second conductivity type which is formed on the semiconductor substrate of the first conductivity type in a concentration of 5×10¹⁷ atoms/cm³ to 1×10¹⁸ atoms/cm³.

13. A method of manufacturing a semiconductor device according to claim 1, wherein the inert element is introduced in the semiconductor layer of the second conductivity type which is formed on the semiconductor substrate of the first conductivity type in a concentration of 5×10¹⁷ atoms/cm³ to 1×10¹⁸ atoms/cm³.
